(19) United States
(12) Patent Application Publication
(10) Pub. No.: US 2014/0253134 A1
(43) Pub. Date: Sep. 11, 2014

(54) ELECTRONIC DEVICE AND METHOD FOR DETECTING THE AMOUNT OF CHARGE OF A BATTERY

(71) Applicant: HTC Corporation, Taoyuan County (TW)

(72) Inventor: Chih-Chung Teng, Taoyuan County (TW)

(73) Assignee: HTC Corporation, Taoyuan County (TW)

(21) Appl. No.: 14/029,826

(22) Filed: Sep. 18, 2013

Related U.S. Application Data
(60) Provisional application No. 61/773,760, filed on Mar. 6, 2013.

(51) Int. Cl. G01R 31/36

(52) U.S. Cl. CPC G01R 31/3606
USPC 324/426

(57) ABSTRACT

An electronic device and a corresponding method for detecting the amount of charge of a battery are provided. The electronic device includes a battery, a detector, and a processor. The battery provides the electric energy needed by the electronic device. The detector detects a parameter of the battery. The parameter is related to the amount of charge of the battery. The detector sends a signal when the parameter changes. The processor obtains the parameter from the detector in response to the signal.

### CROSS-REFERENCE TO RELATED APPLICATION

This application claims the priority benefits of U.S. provisional application Ser. No. 61/773,760, filed on Mar. 6, 2013. The entirety of the above-mentioned patent applications is hereby incorporated by reference herein and made a part of this specification.

### FIELD OF THE INVENTION

The invention relates generally to an electronic device including a battery, and more particularly to an electronic device and a method for detecting the amount of charge of the battery.

### DESCRIPTION OF RELATED ART

Many types of electronic devices, such as the smart phone, the personal digital assistant (PDA), the tablet computer, and the notebook computer utilize a battery as a power source. These electronic devices typically include a detector referred to as the fuel gauge, which is used for detecting parameters of the battery such as the voltage, the current, and the temperature. The central processing unit (CPU) or the processor of the electronic device periodically polls the fuel gauge in order to obtain parameters such as the voltage, the current, and the temperature of the battery, and to calculate the remaining amount of charge of the battery. The calculated remaining amount of charge may be displayed for user view, or utilized in power management of the electronic device.

However, electric energy of the battery is consumed by polling. Moreover, due to frequent polling, noticeable change of the remaining battery charge may be observed only after several polls, and electric energy is consumed by the unnecessary polls.

### SUMMARY OF THE INVENTION

The invention provides an electronic device and a method for detecting the amount of charge of a battery, capable of mitigating the issue of electric energy wastage caused by conventional polling.

An electronic device includes a battery, a detector, and a processor. The battery provides the electric energy needed by the electronic device. The detector is coupled to the battery, and the detector detects a parameter of the battery. The parameter is related to the amount of charge of the battery. The detector sends a signal when a change has occurred on the parameter. The processor is coupled to the detector, and the processor obtains the parameter from the detector in response to the signal.

A method for detecting an amount of charge of a battery includes the following steps: detecting a parameter of the battery, in which the parameter is related to the amount of charge of the battery; sending a signal when a change has occurred on the parameter; and obtaining the parameter in response to the signal.

In summary, according to embodiments of the invention, when a change has occurred on the parameter of the battery, a signal is actively sent to notify the processor to obtain a parameter of the battery, and the processor does not actively poll.

Therefore, embodiments of the invention can mitigate the issue of electric energy wastage caused by conventional polling.

To make the above features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of an electronic device according to an embodiment of the invention.

FIG. 2 is a flow diagram illustrating a method for detecting the amount of charge of a battery according to an embodiment of the invention.

### DETAILED DESCRIPTION OF THE EMBODIMENTS

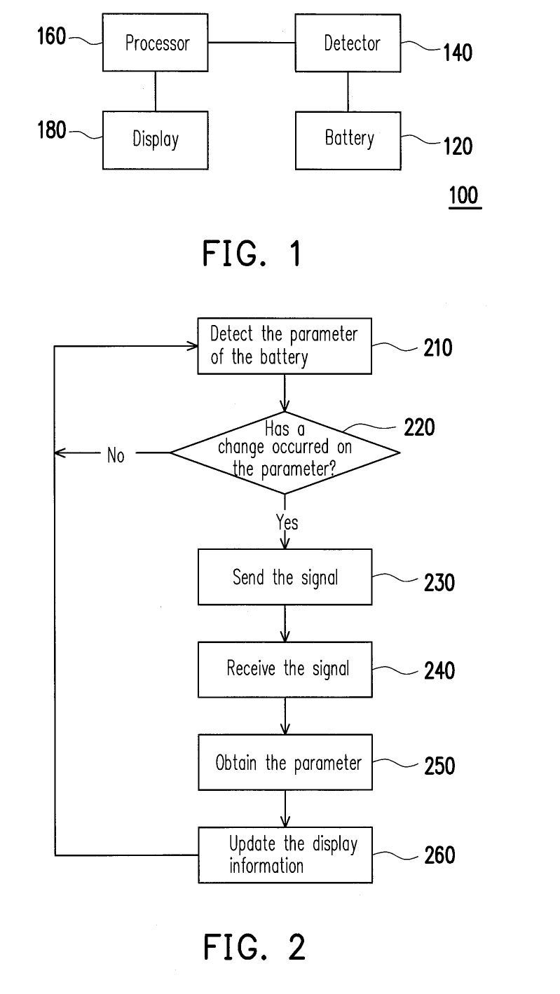

FIG. 1 is a schematic view of an electronic device 100 according to an embodiment of the invention. The electronic device 100 may be any type electronic device which requires a battery to provide the needed electric energy, such as smart phones, PDAs, tablet computers, or notebook computers. The electronic device 100 includes a battery 120, a detector 140, a processor 160, and a display 180. The detector 140 is coupled to the battery 120, and the processor 160 is coupled to the detector 140 and the display 180. The battery 120 provides the electric energy needed by the electronic device 100. The detector 140 may detect a parameter related to the amount of charge of the battery 120. The detector 140 and the processor 160 may execute a method for detecting the amount of charge of the battery depicted in FIG. 2. The display 180 may display information related to the amount of charge of the battery 120.

FIG. 2 is a flow diagram illustrating a method for detecting the amount of charge of a battery according to an embodiment of the invention. In Step 210, the detector 140 detects a parameter of the battery 120. The parameter is related to the amount of charge of the battery 120. The parameter may be related to a remaining amount or a maximum amount of charge of the battery 120, for example, or the parameter may be related to both of the aforementioned amounts of charge of the battery 120. In Step 220, the detector 140 checks whether a change has occurred on the parameter. When no change has occurred, the process returns to Step 210, and the detector 140 continues to detect the parameter of the battery 120. When a change has occurred on the parameter, the detector sends a signal in Step 230. For example, the detector 140 may send an interrupt signal in Step 230.

The change mentioned in Step 220 may refer to: 1) the parameter decreasing a predetermined value or a predetermined percentage, or 2) the parameter decreasing until less than or equal to a predetermined value or a predetermined percentage. For example, the parameter may be the remaining amount of charge of the battery 120, and the detector 140 may send the signal each time the remaining amount of charge decreases by a predetermined value or a predetermined percentage, or the detector 140 may send the signal when the remaining amount of charge decreases to less than or equal to a predetermined value or a predetermined percentage.

Thereafter, the processor 160 receives the parameter in Step 240, and obtains the parameter from the detector 140 in response to the signal in Step S250. The display 180 may display the information related to the amount of charge of the battery 120, in which the information may be a pattern, a character, or a combination of patterns and characters indicating the remaining amount of charge of the battery 120. After the processor 160 obtains the parameter, the processor 160 may update the information displayed by the display 180 according to the parameter in Step 260. The process then returns to Step 210, and the detector 140 continues to detect the parameter of the battery 120.

The detector 140 may calculate the remaining amount of charge of the battery 120. For example, the detector 140 may include a coulomb counter to calculate the remaining amount of charge of the battery 120. The detector 140 may use the remaining amount of charge as the parameter for the processor 160 to obtain. After obtaining the parameter, the processor 160 may calculate a percentage of the remaining amount of charge relative to a maximum amount of charge of the battery 120. The maximum amount of charge may be an internal value of the processor 160 or a value obtained from the detector 140. The percentage may be used for the display 180 to display the aforementioned information, or used for the power management of the electronic device 100, or for other purposes.

Alternatively, the detector 140 may further calculate the percentage of the remaining amount of charge relative to the maximum amount of charge of the battery 120, and use the percentage as the parameter for the processor 160 to obtain.

In some embodiments of the invention, the percentage is not used for the information display of the display 180, but only used for the power management of the electronic device 100, for example. In these embodiments, the display 180 and Step 260 may be omitted.

In view of the foregoing, according to embodiments of the invention, when a change has occurred on the parameter of the battery, the detector actively sends a signal to notify the processor to obtain the parameter. Since the processor does not actively poll, embodiments of the invention can prevent electric energy from being wasted by frequent polling, as well as extend the usage time of the electronic device needing the electric energy provided by the battery.

Although the invention has been described with reference to the above embodiments, it will be apparent to one of ordinary skill in the art that modifications to the described embodiments may be made without departing from the spirit of the invention. Accordingly, the scope of the invention will be defined by the attached claims and not by the above detailed descriptions.

What is claimed is:

1. An electronic device, comprising:
a battery providing electric energy needed by the electronic device;
a detector coupled to the battery, the detector detecting a parameter of the battery, the parameter being related to an amount of charge of the battery, wherein the detector sends a signal when a change has occurred on the parameter; and
a processor coupled to the detector, the processor obtaining the parameter from the detector in response to the signal.

2. The electronic device according to claim 1, wherein the detector is a fuel gauge.

3. The electronic device according to claim 1, wherein the change refers to each time the parameter decreases by a predetermined value or a predetermined percentage.

4. The electronic device according to claim 1, wherein the change refers to the parameter decreasing to less than or equal to a predetermined value or a predetermined percentage.

5. The electronic device according to claim 1, wherein the parameter comprises a remaining amount of charge of the battery, and after obtaining the parameter, the processor calculates a percentage of the remaining amount of charge relative to a maximum amount of charge of the battery.

6. The electronic device according to claim 1, wherein the parameter comprises a percentage of a remaining amount of charge of the battery relative to a maximum amount of charge of the battery.

7. The electronic device according to claim 1, further comprising:
a display coupled to the processor, the display displaying an information related to the amount of charge of the battery, wherein after the processor obtains the parameter, the processor updates the information displayed by the display according to the parameter.

8. A method for detecting an amount of charge of a battery, comprising:
detecting a parameter of the battery, wherein the parameter is related to the amount of charge of the battery;
sending a signal when a change has occurred on the parameter; and
obtaining the parameter in response to the signal.

9. The method for detecting the amount of charge of the battery according to claim 8, further comprising:
using a fuel gauge to detect the parameter of the battery.

10. The method for detecting the amount of charge of the battery according to claim 8, wherein the change refers to each time the parameter decreases by a predetermined value or a predetermined percentage.

11. The method for detecting the amount of charge of the battery according to claim 8, wherein the change refers to the parameter decreasing to less than or equal to a predetermined value or a predetermined percentage.

12. The method for detecting the amount of charge of the battery according to claim 8, wherein the parameter comprises a remaining amount of charge of the battery, and the method further comprises:
after obtaining the parameter, calculating a percentage of the remaining amount of charge of the battery relative to a maximum amount of charge of the battery.

13. The method for detecting the amount of charge of the battery according to claim 8, wherein the parameter comprises a percentage of a remaining amount of charge of the battery relative to a maximum amount of charge of the battery.

14. The method for detecting the amount of charge of the battery according to claim 8, further comprising:
displaying an information related to the amount of charge of the battery; and
after obtaining the parameter, updating the information according to the parameter.
